(19) United States
(12) Patent Application Publication
(10) Pub. No.: US 2008/0237801 A1
(43) Pub. Date: Oct. 2, 2008

(54) Semiconductor device

(75) Inventors: Hideki Kisara, Miyagi (JP); Masao Okihara, Tokyo (JP)

Correspondence Address: KUBOTERA & ASSOCIATES, LLC, Suite 202, 200 Daingerfield Road, Alexandria, VA, 22314, US

(73) Assignee: Oki Electric Industry Co., Ltd.

(21) Appl. No.: 12/076,053

(22) Filed: Mar. 13, 2008

(30) Foreign Application Priority Data
Mar. 27, 2007 (JP) 2007-081760

(51) Int. Cl. H01L 27/00

(52) U.S. Cl. 257/538; 257/E27.006

(57) ABSTRACT

A semiconductor device includes a resistor element formed in a semiconductor layer of an SOI substrate (Silicon On Insulator). The semiconductor device includes a low concentration impurity area formed in the semiconductor layer as the resistor element; a high concentration impurity area formed in the semiconductor layer as a resistor element wiring portion; and a silicide layer selectively formed on the high concentration impurity area. The high concentration impurity area includes one end portion contacting with an end portion of the low concentration impurity area, and the other end portion contacting with an impurity area of another element.

### BACKGROUND OF THE INVENTION AND RELATED ART STATEMENT

The present invention relates to a semiconductor device having a resistor element formed in an SOI (Silicon On Insulator) substrate. In particular, the present invention relates to a semiconductor device, in which a CMOS (Complementary Metal Oxide Semiconductor) device is formed in an SOI (Silicon On Insulator) substrate.

Conventionally, a silicon on insulator (SOI) substrate has been known as a substrate for forming a semiconductor device. In the SOI substrate, a buried oxide film called BOX (Buried Oxide) is formed between a silicon substrate and an SOI layer (single crystal silicon layer). With the configuration, it is possible to reduce a parasite current between a source and a drain. Further, with BOX, it is possible to completely separate each element. Accordingly, it is possible to prevent latch-up and increase a density of a layout. The latch-up is a phenomenon in which a parasite transistor is turned on, and a large current flows.

Further, as opposed to an integrated circuit formed on an ordinary silicon substrate (such as a bulk silicon CMOS circuit), in an integrated circuit formed on the SOI substrate, it is possible to reduce power consumption associated with integration.

For the reasons described above, with the SOI substrate, it is possible to obtain a semiconductor device such as a CMOS device with a high speed and low power consumption. Patent References 1 to 3 have disclosed technologies for forming integrated circuits on the SOI substrate.
Patent Reference 1: Japanese Patent Publication No. 3217336
Patent Reference 2: Japanese Patent Publication No. 2006-108578
Patent Reference 3: Japanese Patent Publication No. 2002-9245

When an analog integrated circuit is formed on a semiconductor substrate, it is necessary to form a passive element such as a resistor element, a capacitor, an inductor, and the likes on the semiconductor substrate. FIGS. 5(A) and 5(B) are view showing a conventional integrated circuit, in which a resistor element is formed on a semiconductor substrate. FIG. 5(A) is a plan view of the semiconductor device, and FIG. 5(B) is a sectional view thereof taken along a line 5(B)-5(B) in FIG. 5(A).

As shown in FIGS. 5(A) and 5(B), the conventional integrated circuit includes a field-effect transistor 510 and resistor elements 520. The field-effect transistor 510 includes high concentration impurity areas 511 and 512 formed in an SOI layer 501. Further, with a gate insulation film 514 therebetween, a gate electrode 515 is formed on a channel forming area 513 between the high concentration impurity areas 511 and 512.

In the conventional analog integrated circuit, the resistor elements 520 include low concentration impurity areas 521 formed in the SOI layer 501. An insulation film 502 is formed on the SOI layer 501. Contacts 503 penetrating through the insulation film 502 are formed on the high concentration impurity areas 511 and 512. Further, contacts 504 penetrating through the insulation film 502 are formed on surfaces at both end portions of the low concentration impurity areas 521. The contacts 503 and 504 are connected through metal wiring portions 505.

In the conventional analog integrated circuit, the resistor elements 520 are connected to other elements such as field-effect transistors through the contact 504 and the metal wiring portions 505. When it is necessary to provide a high resistivity, a plurality of resistor elements 520 is arranged in a ladder shape as shown in FIG. 5(A). Then, a plurality of resistor elements 520 is connected through the contact 504 and the metal wiring portions 505.

In the conventional analog integrated circuit shown in FIG. 5(A), it is necessary to arrange the elements in a limited layout including a parameter such as a gate distance of the field-effect transistor 510, a distance between the contacts 503 and 504, an arrangement of the metal wiring portion 505 and the contacts 503 and 504, and the likes. Accordingly, it is difficult to obtain a sufficiently high resistivity in a limited area.

In view of the problems described above, an object of the present invention is to provide a semiconductor device, in which it is possible to form a resistor element in an integrated circuit with a minimized limitation to a layout thereof, and to obtain a sufficiently high resistivity in a small area.

Further objects and advantages of the invention will be apparent from the following description of the invention.

### SUMMARY OF THE INVENTION

In order to attain the objects described above, according to a first aspect of to the present invention, a semiconductor device includes a resistor element formed in a semiconductor layer of an SOI substrate (Silicon On Insulator). The semiconductor device includes a low concentration impurity area formed in the semiconductor layer as the resistor element; a high concentration impurity area formed in the semiconductor layer as a resistor element wiring portion; and a silicide layer selectively formed on the high concentration impurity area. The high concentration impurity area includes one end portion contacting with an end portion of the low concentration impurity area, and the other end portion contacting with an impurity area of another element.

According to a second aspect of the present invention, a semiconductor device includes a resistor element formed in a semiconductor layer of an SOI substrate (Silicon On Insulator). The resistor element includes a low concentration impurity area formed in the semiconductor layer as a resistor element; a first high concentration impurity area and a second high concentration impurity area formed in the semiconductor layer as resistor element wiring portions; and a gate electrode formed on the semiconductor layer for separating one of the first high concentration impurity area and the second high concentration impurity area from the low concentration impurity area with a depleted layer. The first high concentration impurity area and the second high concentration impurity area contact with corresponding end portions of the low concentration impurity area.

In the first aspect of to the present invention, the low concentration impurity area is connected to the low concentration impurity area of another element through the high concentration impurity area. Accordingly, it is possible to form the resistor element in an integrated circuit with a minimized limit to a layout thereof. Further, the silicide layer is formed on the high concentration impurity area. Accordingly, it is possible to reduce only a resistivity of the high concentration impurity area, thereby obtaining a high resistivity.

In the second aspect of to the present invention, the gate electrode forms the depleted layer. Accordingly, it is possible to form the resistor element in a ladder shape, thereby obtaining a high resistivity in a small area.

### BRIEF DESCRIPTION OF THE DRAWINGS

FIGS. 1(A) and 1(B) are schematic views showing a semiconductor device according to a first embodiment of the present invention, wherein FIG. 1(A) is a plan view of the semiconductor device, and FIG. 1(B) is a sectional view thereof taken along a line 1(B)-1(B) in FIG. 1(A);

FIGS. 2(A) to 2(C) are schematic sectional views showing a process of manufacturing the semiconductor device according to the first embodiment of the present invention;

FIGS. 3(A) to 3(C) are schematic sectional views showing the process of manufacturing the semiconductor device according to the first embodiment of the present invention;

FIGS. 4(A) and 4(B) are schematic views showing a semiconductor device according to a second embodiment of the present invention, wherein FIG. 4(A) is a plan view of the semiconductor device, and FIG. 4(B) is a sectional view thereof taken along a line 4(B)-4(B) in FIG. 4(A); and

FIGS. 5(A) and 5(B) are schematic views showing a conventional semiconductor device, wherein FIG. 5(A) is a plan view of the semiconductor device, and FIG. 5(B) is a sectional view thereof taken along a line 5(B)-5(B) in FIG. 5(A).

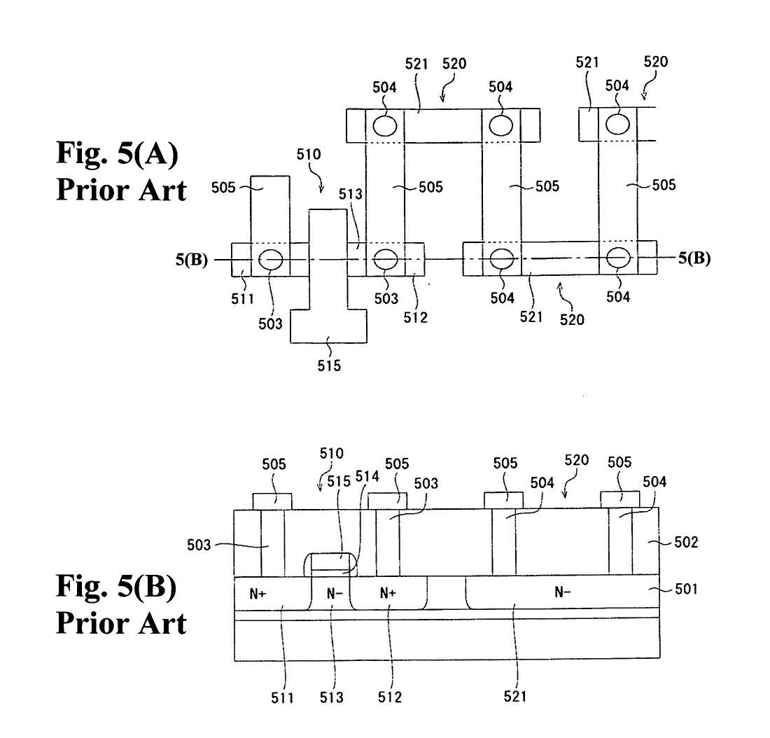

### DETAILED DESCRIPTION OF PREFERRED EMBODIMENTS

Hereunder, embodiments of the present invention will be explained with reference to the accompanying drawings. In the following description of the present invention, each of the drawings is illustrated schematically in terms of a shape, a size, and a dimensional relationship for explaining the embodiments of the present invention, and the present invention is not limited to the shape, the size, and the dimensional relationship shown in the drawings.

### First Embodiment

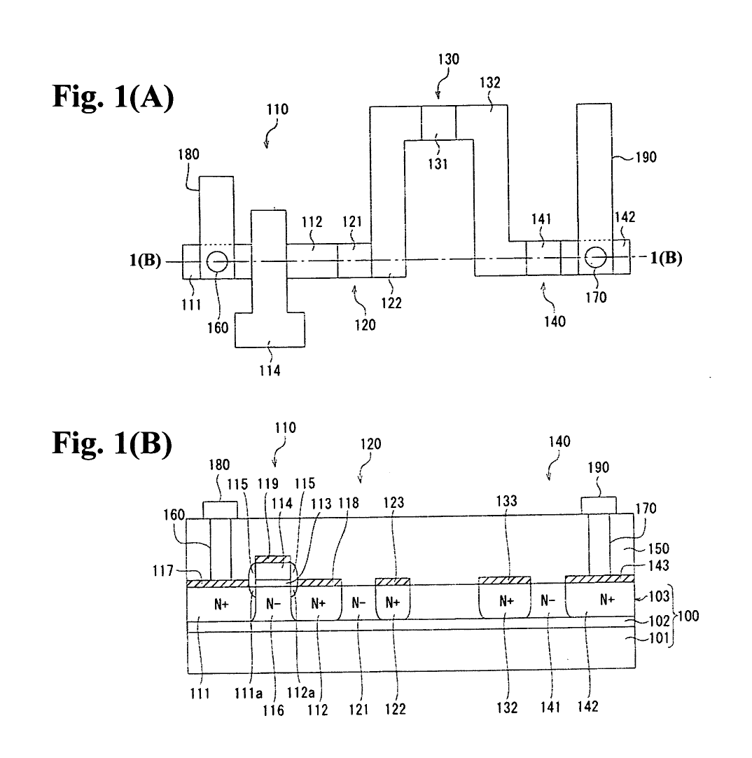

A first embodiment of the present invention will be explained with reference to FIGS. 1(A) and 1(B) to 3(A) to 3(D). FIGS. 1(A) and 1(B) are schematic views showing a semiconductor device according to the first embodiment of the present invention. More specifically, FIG. 1(A) is a plan view of the semiconductor device, and FIG. 1(B) is a sectional view thereof taken along a line 1(B)-1(B) in FIG. 1(A).

As shown in FIG. 1(B), the semiconductor device is formed on an SOI (Silicon On Insulator) substrate 100. The SOI substrate 100 includes a silicon substrate 101, an oxide film 102, and an SOI (Silicon On Insulator) layer 103. The semiconductor device includes a field-effect transistor 110 and resistor circuits 120, 130, and 140.

In the embodiment, the field-effect transistor 110 includes high concentration impurity areas 111 and 112; a gate insulation film 113; a gate electrode 114; sidewalls 115; a channel forming area 116; and silicide layers 117 to 119. The high concentration impurity areas 111 and 112 are formed in the SOI layer 103 as a source area and a drain area. Further, the high concentration impurity areas 111 and 112 include LDD (Lightly Doped Drain) areas 111a and 112a.

In the embodiment, the channel forming area 116 is disposed between the high concentration impurity areas 111 and 112. The gate insulation film 113 and the gate electrode 114 are formed on the channel forming area 116. The sidewalls 115 are formed on side surfaces of the gate insulation film 113 and the gate electrode 114. The silicide layers 117, 118, and 119 are selectively formed on the high concentration impurity areas 111 and 112 and the gate electrode 114, respectively. The silicide layers 117, 118, and 119 are formed of, for example, CoSi₂.

In the embodiment, the resistor circuit 120 includes a low concentration impurity area 121 as a resistor element; high concentration impurity areas 112 and 122 as resistor element wiring portions; and a silicide layer 123.

In the embodiment, the low concentration impurity area 121 is a high resistivity area formed in the SOI layer 103. A resistivity of the low concentration impurity area 121 is determined according to a design of an analog integrated circuit, and is within a range of, for example, a few ohms to a few kilo-ohms.

In the embodiment, the high concentration impurity areas 112 and 122 are low resistivity areas formed in the SOI layer 103. The high concentration impurity areas 112 and 122 have one end portions contacting with end portions of the low concentration impurity area 121 and the other end portions contacting with low concentration impurity areas 116 and 131 of other elements, respectively.

As described above, in the resistor circuit 120, the low concentration impurity area 121 or the high resistivity area is connected to the field-effect transistor 110 and the resistor circuit 130 through the high concentration impurity areas 112 and 122 without a contact or a metal wiring portion. Further, the resistor circuit 120 shears the high concentration impurity area 112 with the field-effect transistor 110, and shears the high concentration impurity area 122 with the resistor circuit 130.

In the embodiment, the silicide layer 123 is selectively formed on the high concentration impurity area 122, and may be formed of, for example, CoSi₂. With the silicide layer 123, a resistivity of the high concentration impurity area 122 is lowered.

In the embodiment, the resistor circuit 130 includes a low concentration impurity area 131; high concentration impurity areas 122 and 132; and a silicide layer 133.

In the embodiment, similar to the resistor circuit 120, the low concentration impurity area 131 is a high resistivity area formed in the SOI layer 103. A resistivity of the low concentration impurity area 131 is determined according to a design of an analog integrated circuit, and is within a range of, for example, a few ohms to a few kilo-ohms.

In the embodiment, the high concentration impurity area 132 is a low resistivity area formed in the SOI layer 103. The high concentration impurity area 132 has one end portion contacting with an end portion of the low concentration impurity area 131 and the other end portion contacting with a low concentration impurity area 141 of the resistor circuit 140.

As described above, in the resistor circuit 130, the low concentration impurity area 131 is sheared with the high concentration impurity area 122 of the resistor circuit 120, and the high concentration impurity area 132 is sheared with the low concentration impurity area 141 of the resistor circuit 140. Similar to the resistor circuit 120, the low concentration impurity area 131 is connected to the resistor circuit 120 and the resistor circuit 140 through the high concentration impurity areas 122 and 132 without a contact or a metal wiring portion.

In the embodiment, similar to the silicide layer 123, the silicide layer 133 is selectively formed on the high concentration impurity area 132, and may be formed of, for example, CoSi₂. With the silicide layer 133, a resistivity of the high concentration impurity area 132 is lowered.

In the embodiment, the resistor circuit 140 includes the low concentration impurity area 141; high concentration impurity areas 132 and 142; and a silicide layer 143. Similar to the resistor circuit 120 and the resistor circuit 130, the low concentration impurity area 141 is a high resistivity area formed in the SOI layer 103. A resistivity of the low concentration impurity area 141 is determined according to a design of an analog integrated circuit, and is within a range of, for example, a few ohms to a few kilo-ohms.

In the embodiment, the high concentration impurity area 142 is a low resistivity area formed in the SOI layer 103. The high concentration impurity area 142 has one end portion contacting with an end portion of the low concentration impurity area 141. As described above, in the resistor circuit 140, the low concentration impurity area 141 is sheared with the high concentration impurity area 132 of the resistor circuit 130. Similar to the resistor circuit 120, the low concentration impurity area 141 is connected to the resistor circuit 130 through the high concentration impurity area 132 without a contact or a metal wiring portion.

In the embodiment, the silicide layer 143 is selectively formed on the high concentration impurity area 142, and may be formed of, for example, CoSi₂ similar to the field-effect transistor 110. With the silicide layer 143, a sheet resistivity of the high concentration impurity area 142 is lowered.

In the embodiment, an insulation film 150 is formed on a surface of the SOI substrate 100. Further, contact layers 160 and 170 are formed to penetrate the insulation film 150. The contact layer 160 contacts with the high concentration impurity area 111 through the silicide layer 117, and the contact layer 170 contacts with the high concentration impurity area 142 through the silicide layer 143. Metal wiring portions 180 and 190 are formed on a backside surface of the insulation film 150 to contact with the contact layers 160 and 170, respectively.

As described above, the semiconductor device is provided with the silicide layer 117 and the silicide layer 143. Normally, the SOI layer 103 has a sheet resistivity of a few hundreds of ohms. When the SOI layer 103 has a high sheet resistivity, a parasite Schottky resistor might be generated at a contact surface between the high concentration impurity areas 111 and 142 and the contact layers 160 and 170. On the other hand, the silicide layer 123, the silicide layer 133, and the silicide layer 143 have a low sheet resistivity of a few tens of ohms. Accordingly, when the silicide layer 117 and the silicide layer 143 are provided, it is possible to prevent a parasite Schottky resistor.

Further, in the resistor circuits 120, 130, and 140, the silicide layers 118, 123, 133, and 143 are selectively formed only on the high concentration impurity areas 111, 122, 132, and 142 (no silicide layers on the low concentration impurity areas 121, 131, and 141), respectively. Accordingly, it is possible to reduce only a resistivity of the high concentration impurity areas 111, 122, 132, and 142. In other words, while the resistor element wiring portions have a sufficiently low resistivity, the resistor circuits 120, 130, and 140 have a sufficiently high resistivity.

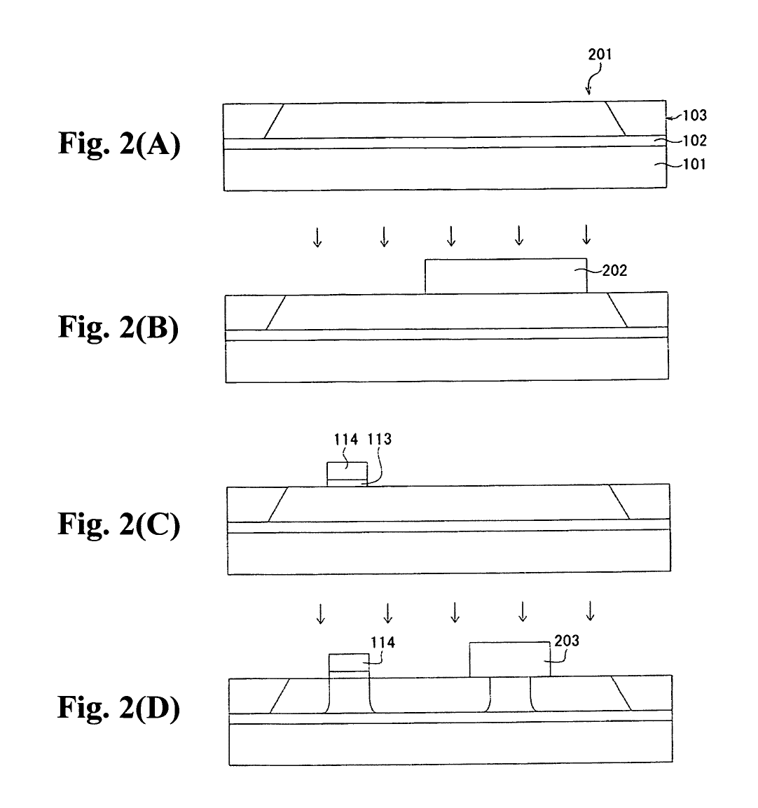

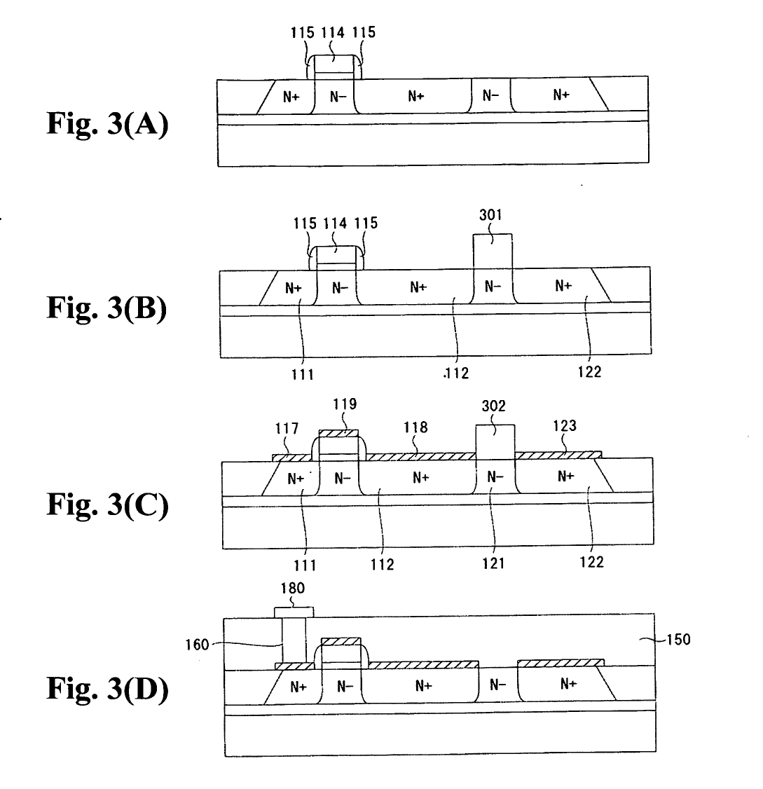

A method of producing the semiconductor device shown in FIGS. 1(A) and 1(B) will be explained next with reference to FIGS. 2(A)-2(D) and 3(A)-3(D). For a simple explanation, only a method of producing the field-effect transistor 110 and the resistor circuit 120 will be explained.

In the first step, as shown in FIG. 2(A), an element area 201 is formed in the SOI layer 103 using an element separation technology such as a LOCOS (Localized Oxidation of Silicon) method and an STI (Shallow Trench Isolation) method.

In the next step, a resist film 202 is formed with a normal photolithography method, so that a circuit forming area is covered. After ions are introduced into the surface of the SOI layer 103 as shown in FIG. 2(B), the resist film 202 is removed. Through the introduction of ions, an operation threshold value Vt of the field-effect transistor 110 is determined. If necessary, ions are further introduced to determine a resistivity of the resistor circuits 120, 130, and 140.

In the next step, after the gate insulation film 113 is formed through, for example, a thermal oxidation method, a conductive film is formed on a whole area of the SOI layer 103. More specifically, the conductive film is formed of a poly-silicon using a thin film forming method such as a CVD method. As shown in FIG. 2(C), the conductive film is patterned using a photolithography technology and an etching technology to form the gate electrode 114.

In the next step, a resist film 203 is formed with a normal photolithography method, so that an area for forming the low concentration impurity area 121 of the resistor circuit 120 is covered. As shown in FIG. 2(D), ions are introduced to form the LDD (Lightly Doped Drain) area of the field-effect transistor 110 with the resist film 203 and the gate electrode 114 as a mask.

In the next step, as shown in FIG. 3(A), the sidewalls 115 are formed on the side surfaces of the gate electrode 114 with a well-known process.

In the next step, as shown in FIG. 3(B), a resist film 301 is formed with a normal photolithography method, so that an area for forming the low concentration impurity area 121 of the resistor circuit 120 is covered. Then, ions are introduced to form the high concentration impurity areas 111 and 112 of the field-effect transistor 110 and the high concentration impurity area 122 of the resistor circuit 120 with the resist film 301, the gate electrode 114, and the sidewalls 115 as a mask.

In the next step, an insulation film such as an NSG film is deposited on the whole area of the SOI layer 103. Then, the insulation film is patterned with a photolithography technology and the likes to form a protective film 302 for covering the low concentration impurity area 121 of the resistor circuit 120. With the protective film 302, it is possible to prevent the low concentration impurity area 121 from becoming silicide in a silicide layer forming process (described later).

In the next step, as shown in FIG. 3(C), the silicide layers 117, 118, 119, and 123 (formed of CoSi₂ in the embodiment) are selectively formed on the gate electrode 114, and the high concentration impurity areas 111, 112, and 122, respectively.

In the next step, as shown in FIG. 3(D), the insulation film 150, the contact layer 160, the metal wiring portion 180, and the likes are formed with a well-known process technology.

As described above, in the embodiment, the low concentration impurity areas 121, 131, and 141 of the resistor circuits 120, 130, and 140 are connected to the impurity areas of the other elements through the high concentration impurity areas 112, 122, and 132 without a contact or a metal wiring portion. Accordingly, it is possible to arrange the resistor circuits 120, 130, and 140 in the integrate circuit with a minimized layout limitation.

Further, in the resistor circuits 120, 130, and 140, the silicide layers 117, 118, 123, 133, and 143 are selectively formed only on the high concentration impurity areas 111, 112, 122, 132, and 142 (no silicide layers on the low concentration impurity areas 121, 131, and 141). Accordingly, it is possible to reduce only a resistivity of the high concentration impurity areas 111, 112, 122, 132, and 142, and to maintain a sufficiently high resistivity of the resistor circuits 120, 130, and 140.

### Second Embodiment

A second embodiment of the present invention will be explained next. Components in the second embodiment similar to those in the first embodiment are designated by the same reference numerals, and explanations thereof are omitted.

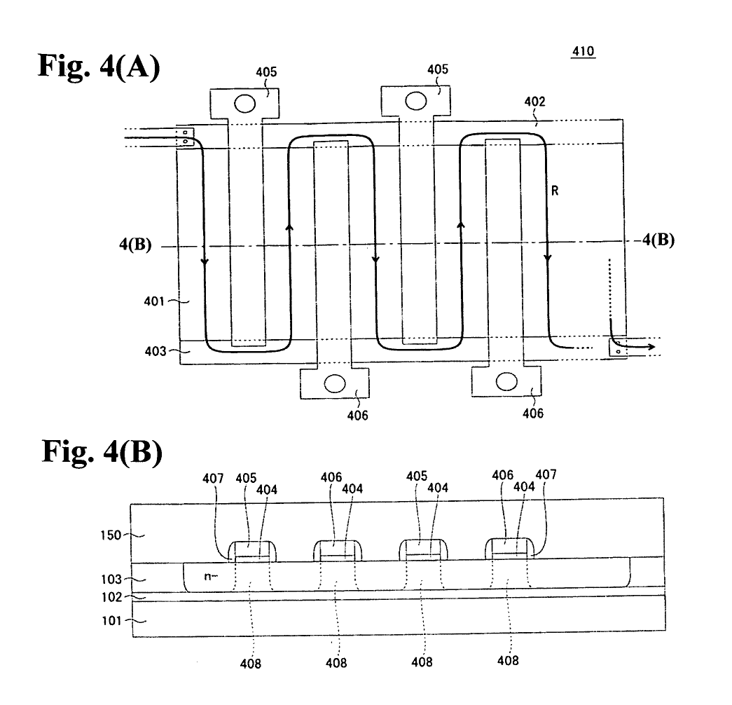

FIGS. 4(A) and 4(B) are schematic views showing a semiconductor device according to the second embodiment of the present invention. FIG. 4(A) is a plan view of the semiconductor device, and FIG. 4(B) is a sectional view thereof taken along a line 4(B)-4(B) in FIG. 4(A).

As shown in FIG. 4(B), the semiconductor device includes a low concentration impurity area 401; first and second high concentration impurity areas 402 and 403; gate insulation films 404; first and second gate electrodes 405 and 406; and sidewalls 407, thereby forming one single resistor circuit 410.

In the embodiment, the low concentration impurity area 401 is a high resistivity area formed in the SOI layer 103, and has a rectangular shape. The first high concentration impurity area 402 is formed in the SOI layer 103, and is arranged to contact with a corresponding side of the low concentration impurity area 401. The second high concentration impurity area 403 is formed in the SOI layer 103, and is arranged to contact with a side of the low concentration impurity area 401 opposite to the first high concentration impurity area 402.

In the embodiment, the gate insulation films 404 are formed on areas of the low concentration impurity area 401 where at least the first and second gate electrodes 405 and 406 are formed. The first gate electrodes 405 are formed on the SOI layer 103. More specifically, the first gate electrodes 405 are arranged to cross the low concentration impurity area 401 and the first high concentration impurity area 402. Further, the first gate electrodes 405 are arranged to contact with only a part of the second high concentration impurity area 403 (including at least a boundary of the low concentration impurity area 401 and the second high concentration impurity area 403).

With the configuration described above, when a specific potential is applied to the first gate electrodes 405, depleted layers are generated. Accordingly, it is possible to divide the low concentration impurity area 401 and the first high concentration impurity area 402 just below the first gate electrodes 405 (described later).

In the embodiment, the second gate electrodes 406 are formed on the SOI layer 103. More specifically, the second gate electrodes 406 are arranged to cross the low concentration impurity area 401 and the second high concentration impurity area 403. Further, the second gate electrodes 406 are arranged to contact with only a part of the first high concentration impurity area 402 (including at least a boundary of the low concentration impurity area 401 and the first high concentration impurity area 402).

With the configuration described above, when a specific potential is applied to the second gate electrodes 406, depleted layers are generated. Accordingly, it is possible to divide the low concentration impurity area 401 and the second high concentration impurity area 403 just below the second gate electrodes 406 (described later).

In the embodiment, the sidewalls 407 are formed to cover side surfaces of the first and second gate electrodes 405 and 406.

With the configuration described above, when the semiconductor is operated, a specific potential is applied to the first and second gate electrodes 405 and 406. Accordingly, the portions of the impurity areas 401, 402, and 403 just below the first and second gate electrodes 405 and 406 become a depleted state, thereby forming depleted layers 408 (see FIG. 4(B)). In this case, the depleted layers 408 are substantially insulation areas. In other words, portions of the impurity areas 401, 402, and 403 where do not become the depleted state become a current path (refer to an arrow R in FIG. 4(A)).

As described above, the low concentration impurity area 401 has a high resistivity, and the high concentration impurity areas 402 and 403 have a low resistivity. Accordingly, with the depleted layers 408, it is possible to obtain the resistor circuit 410 having a substantially ladder shape.

In the embodiment, the first and second gate electrodes 405 and 406 may be arranged such that a potential can be separately applied to at least a specific one of the first and second gate electrodes 405 and 406 or no potential is applied to at least a specific one of the first and second gate electrodes 405 and 406. Accordingly, it is possible to selectively apply a potential to arbitral one or more gate electrodes.

When a gate potential is selectively applied to a selected gate electrode, the depleted layer 408 is generated under the gate electrode thus selected, and is not generated under the gate electrode thus not selected. As a result, it is possible to freely set a width and a length of the current path, thereby adjusting a resistivity of the resistor circuit 410.

When the depleted layers 408 are generated with the first and second gate electrodes 405 and 406 as described above, the SOI substrate 100 may have the SOI layer 103 having a sufficiently small thickness.

A process of producing the semiconductor device in the second embodiment is the same as that of the semiconductor device in the first embodiment, and explanations thereof are omitted.

As described above, in the second embodiment, the depleted layers 408 are generated with the first and second gate electrodes 405 and 406. Accordingly, it is possible to obtain the resistor circuit 410 having a ladder shape. Further, it is possible to obtain the resistor circuit 410 having a high resistivity and a small area.

The disclosure of Japanese Patent Application No. 2007-081760, filed on Mar. 27, 2007, is incorporated in the application by reference.

While the invention has been explained with reference to the specific embodiments of the invention, the explanation is illustrative and the invention is limited only by the appended claims.

What is claimed is:

1. A semiconductor device comprising:
an SOI (Silicon On Insulator) substrate having a semiconductor layer;
a low concentration impurity area formed in the semiconductor layer as a first resistor element;
a high concentration impurity area formed in the semiconductor layer as a resistor element wiring portion, said high concentration impurity area including one end portion contacting with an end portion of the low concentration impurity area and the other end portion contacting with an impurity area of another element; and
a silicide layer selectively formed on the high concentration impurity area.

2. The semiconductor device according to claim 1, further comprising an insulation film covering a surface of the SOI substrate.

3. The semiconductor device according to claim 2, further comprising a contact layer penetrating the insulation film for contacting the silicide layer.

4. The semiconductor device according to claim 1, further comprising a field-effect transistor formed in the semiconductor layer, said field-effect transistor including the high concentration impurity area.

5. The semiconductor device according to claim 1, further comprising a second resistor element formed in the semiconductor layer, said second resistor element including the high concentration impurity area.

6. A semiconductor device comprising:
an SOI (Silicon On Insulator) substrate having a semiconductor layer;
a low concentration impurity area formed in the semiconductor layer as a resistor element;
a first high concentration impurity area formed in the semiconductor layer as a first resistor element wiring portion, said first high concentration impurity area contacting with a first end portion of the low concentration impurity area;
a second high concentration impurity area formed in the semiconductor layer as a second resistor element wiring portion, said second high concentration impurity area contacting with a second end portion of the low concentration impurity area; and
a gate electrode formed on the semiconductor layer for forming a depleted layer to divide the low concentration impurity area and at least one of the first high concentration impurity area and the second high concentration impurity area.

7. The semiconductor device according to claim 6, wherein said gate electrode includes a first gate electrode and a second gate electrode arranged alternately, said first gate electrode being adapted to form a first depleted layer for dividing the low concentration impurity area and the first high concentration impurity area, said second gate electrode being adapted to form a second depleted layer for dividing the low concentration impurity area and the second high concentration impurity area.

8. The semiconductor device according to claim 6, wherein said gate electrode includes a plurality of electrodes so that at least one of the electrodes is selected to form the depleted layer.
